(19) United States
(12) Patent Application Publication
(10) Pub. No.: US 2023/0122846 A1
(43) Pub. Date: Apr. 20, 2023

(54) FEATURE FILL WITH NUCLEATION INHIBITION

(71) Applicant: Lam Research Corporation, Fremont, CA (US)

(72) Inventors: Rohit KHARE, San Ramon, CA (US); Krishna BIRRU, Fremont, CA (US); Gang L. LIU, Fremont, CA (US); Anand CHANDRASHEKAR, Fremont, CA (US); Leonard Wai Fung KHO, San Francisco, CA (US)

(21) Appl. No.: 17/907,377

(22) PCT Filed: Mar. 12, 2021
(86) PCT No.: PCT/US2021/022152

§ 371 Date: Sep. 26, 2022

Related U.S. Application Data
(60) Provisional application No. 63/000,646, filed on Mar. 27, 2020.

(51) Int. Cl. H01L 21/768

(52) U.S. Cl. CPC H01L 21/76883

(57) ABSTRACT

Provided herein are methods of filling features with metal including inhibition of metal nucleation. Also provided are methods of enhancing inhibition and methods of reducing or eliminating inhibition of metal nucleation.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in their entireties and for all purposes.

### BACKGROUND

Deposition of metals in features is an integral part of many semiconductor fabrication processes. The deposited metal films may be used for horizontal interconnects, vias between adjacent metal layers, and contacts between metal layers and devices. In an example of deposition, a tungsten (W) layer may be deposited on a titanium nitride (TiN) barrier layer to form a TiN/W bilayer by a chemical vapor deposition (CND) process using tungsten hexafluoride (WF₆). However, as devices shrink and more complex patterning schemes are utilized in the industry, deposition of thin metal films becomes a challenge. The continued decrease in feature size and film thickness bring various challenges to metal film stacks including filling features with void free film. Deposition in complex high aspect ratio structures such as 3D NAND structures is particularly challenging.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

Provided herein are methods of filling features with metal including inhibition of metal nucleation. Also provided are methods of enhancing inhibition and methods of reducing or eliminating inhibition of metal nucleation.

One aspect of the disclosure relates to a method including exposing a metal surface in a feature to a plasma comprising nitrogen species to inhibit metal nucleation on the metal surface; and after exposing the metal surface to the plasma including nitrogen species, exposing the feature to a plasma comprising oxygen species and no nitrogen species to further inhibit metal nucleation on the metal surface. The further inhibition is performed prior to metal deposition in the feature including the inhibited surface. In some embodiments, the method further includes, after exposing the metal surface to the plasma including oxygen species, depositing metal in the feature. In some embodiments, the metal surface is one of a tungsten (W), molybdenum (Mo), ruthenium (Ru), or cobalt (Co) surface. In some embodiments, the nitrogen species are nitrogen radicals. In some embodiments, the oxygen species are oxygen radicals. In some embodiments, exposing the metal surface to the plasma including nitrogen species forms a metal nitride. In some embodiments, exposing the feature to the plasma including oxygen species forms a metal oxynitride.

Another aspect of the disclosure relates to method including, after a treatment process that inhibits metal nucleation on a surface, exposing the treated surface to a plasma including oxygen species and nitrogen species to de-inhibit metal nucleation on the surface. The de-inhibition may be performed prior to any metal deposition in the feature including the inhibited surface. In some embodiments, the method further includes, prior to deposition on the surface and after de-inhibiting the surface, exposing the surface to nitrogen species to inhibit metal nucleation on the surface. In some embodiments, one of a tungsten (W), molybdenum (Mo), ruthenium (Ru), or cobalt (Co) nucleation is inhibited.

These and other aspects of the disclosure are discussed further below with reference to the drawings.

### BRIEF DESCRIPTION OF FIGURES

FIGS. 1A and 1B are schematic examples of material stacks that include a conductive metal layer according to various embodiments.

FIGS. 2A-2K are schematic examples of various structures into which a metal fill layer may be deposited in accordance with disclosed embodiments.

FIG. 3A is a process flow diagram illustrating operations in filling a structure with a metal according to various embodiments.

FIG. 3B shows a schematic of a cross-section of feature at various stages in according to an embodiment of the process in FIG. 3A.

FIG. 4 shows an example of a process flow diagram illustrating operations in a method of increasing a nucleation delay.

FIG. 5 shows an example of a process flow diagram illustrating operations in a method of filling a feature with metal.

FIG. 6 shows an example of a process flow diagram illustrating certain operations in a method of inhibiting a surface with a reset.

FIG. 7 show a schematic of a process system in accordance with certain embodiments.

FIG. 8 shows a schematic of a processing station in accordance with certain embodiments.

### DETAILED DESCRIPTION

In the following description, numerous specific details are set forth to provide a thorough understanding of the presented embodiments. The disclosed embodiments may be practiced without some or all these specific details. In other instances, well-known process operations have not been described in detail to not unnecessarily obscure the disclosed embodiments. While the disclosed embodiments will be described in conjunction with the specific embodiments, it will be understood that it is not intended to limit the disclosed embodiments.

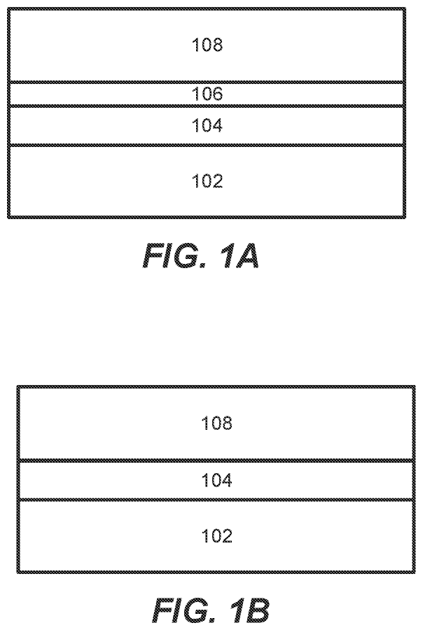

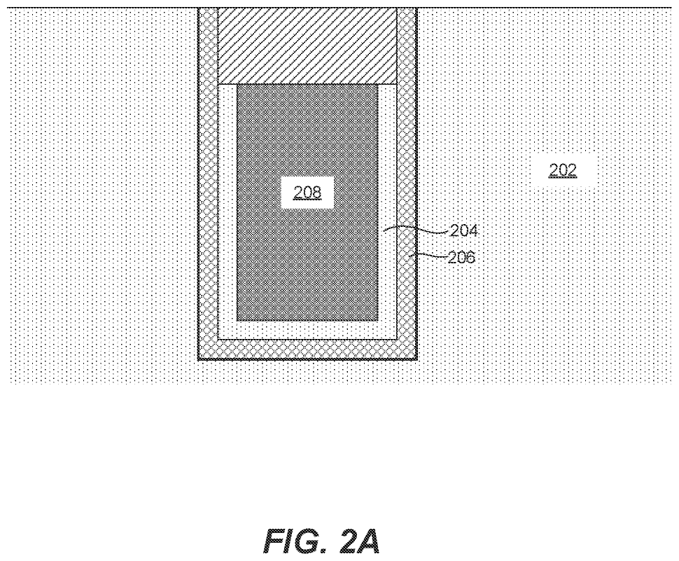

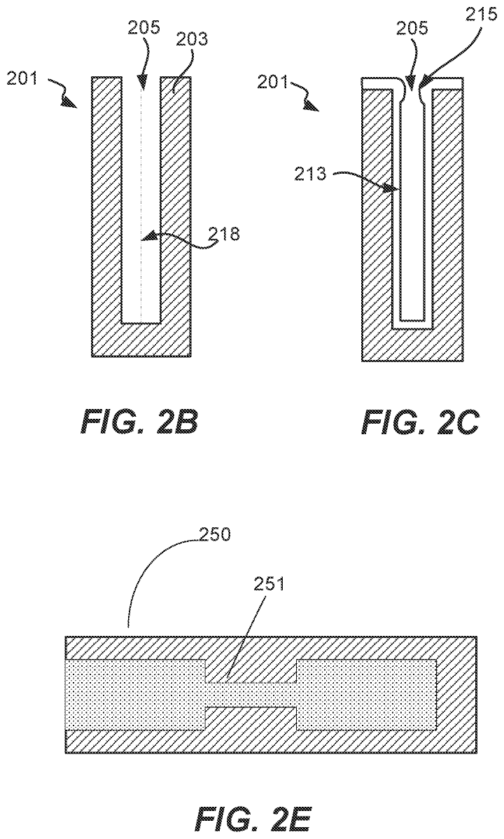

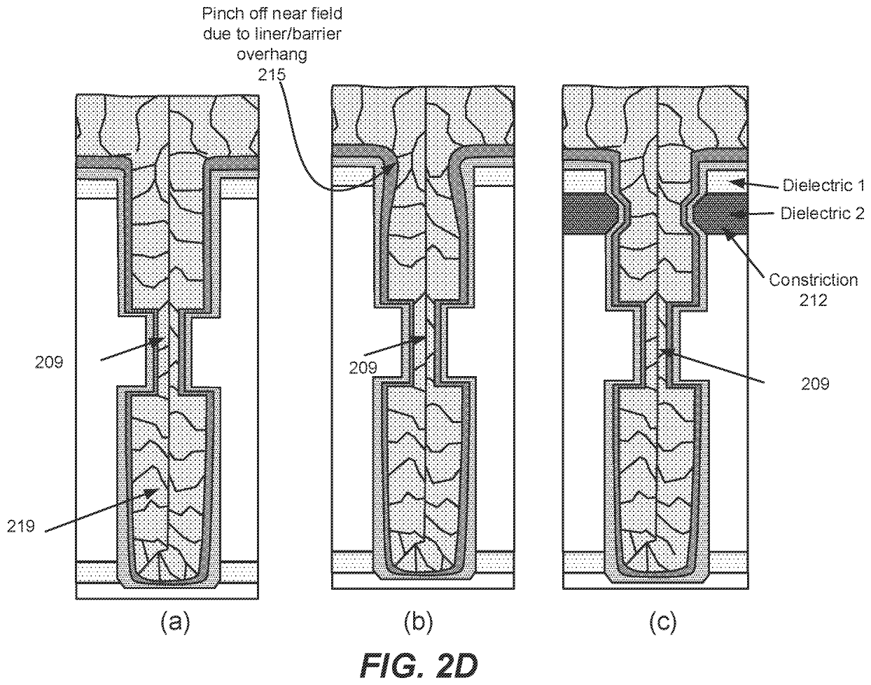

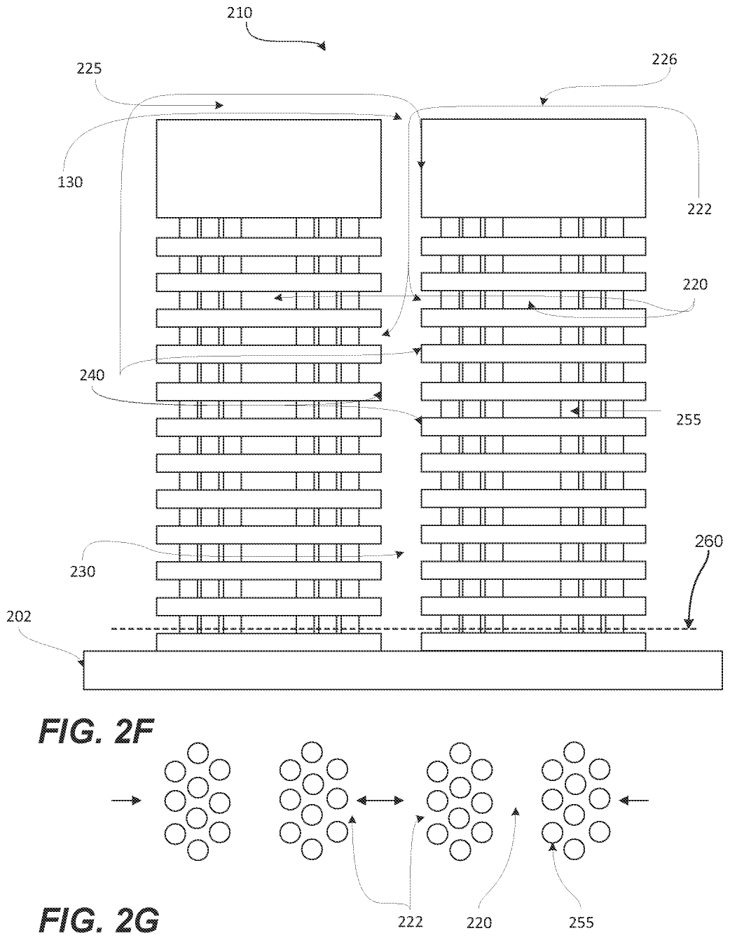

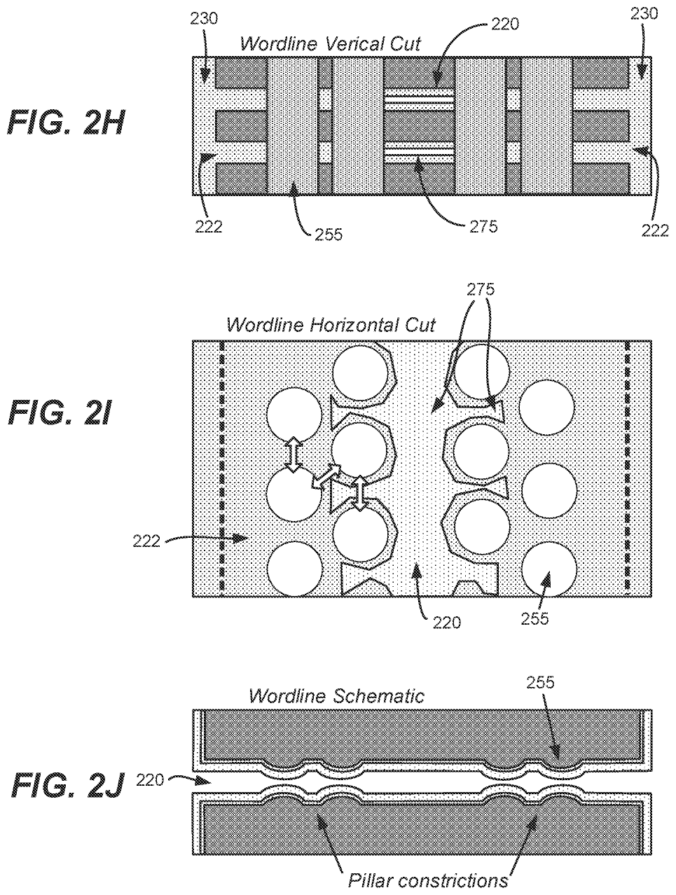

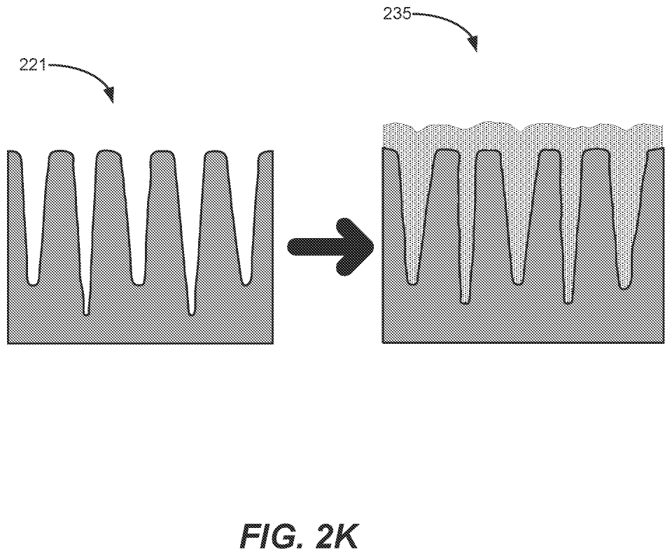

Provided herein are methods of filling features with metal such as tungsten (W), molybdenum (Mo), cobalt (Co), and ruthenium (Ru) that may be used for logic and memory applications. FIGS. 1A and 1B are schematic examples of material stacks that include a conductive metal layer according to various embodiments. FIGS. 1A and 1B illustrate the order of materials in a particular stack and may be used with any appropriate architecture and application, as described further below with respect to FIGS. 2A-2K. In the example of FIG. 1A, a substrate 102 has a conductive metal layer 108 deposited thereon. The substrate 102 may be a silicon or other semiconductor wafer, e.g., a 200-mm water, a 300-mm wafer, or a 450-mm wafer, including wafers having one or more layers of material, such as dielectric, conducting, or semi-conducting material deposited thereon. The methods may also be applied to form metallization stack structures on other substrates, such as glass, plastic, and the like.

In FIG. 1A, a dielectric layer 104 is on the substrate 102. The dielectric layer 104 may be deposited directly on a semiconductor (e.g., Si) surface of the substrate 102, or there may be any number of intervening layers. Examples of dielectric layers include doped and undoped silicon oxide, silicon nitride, and aluminum oxide layers, with specific examples including doped or undoped layers s SiO₂ and Al₂O₃. Also, in FIG. 1A, a diffusion barrier layer 106 is disposed between the conductive metal layer 108 and the dielectric layer 104. Examples of diffusion barrier layers including titanium nitride (TiN), titanium/titanium nitride (Ti/TiN), tungsten nitride (WN), and tungsten carbon nitride (WCN). Further examples of diffusion barriers are multi-component Mo-containing films such as molybdenum nitride (MoN). The conductive metal layer 108 is the main conductor of the structure. In some embodiments, the conductive metal layer 108 may include multiple bulk layers deposited at different conditions. The conductive metal layer 108 may or may not include a nucleation layer, e.g., the conductive metal layer 108 may include a W bulk layer deposited on W nucleation layer. In some embodiments, a metal layer of one metal (e.g., Mo) may be deposited on a thin growth initiation layer of another metal (e.g., W).

FIG. 1B shows another example of a material stack. In this example, the stack includes the substrate 102, dielectric layer 104, with conductive metal layer 108 deposited directly on the dielectric layer 104, without an intervening diffusion barrier layer. The conductive metal layer 108 is as described with respect to FIG. 1A.

While FIGS. 1A and 1B show examples of metallization stacks, the methods and resulting stacks are not so limited. For example, in some embodiments, the metal conductive layer may be deposited directly on a Si or other semiconductor substrate, with or without a nucleation or initiation layer. FIGS. 1A and 1B illustrate examples of order of materials in a particular stack and may be used with any appropriate architecture and application, with examples of different applications and architectures described further below with respect to FIGS. 2A-2J.

The methods described herein are performed on a substrate that may be housed in a chamber. The substrate may be a silicon or other semiconductor wafer, e.g., a 200-mm wafer, a 300-mm wafer, or a 450-mm wafer, including wafers having one or more layers of material, such as dielectric, conducting, or semi-conducting material deposited thereon. The methods are not limit to semiconductor substrates and may be performed to fill any feature with a metal-containing material.

Substrates may have features such as via or contact holes, which may be characterized by one or more of narrow and/or re-entrant openings, constrictions within the feature, and high aspect ratios. A feature may be formed in one or more of the above described layers. For example, the feature may be formed at least partially in a dielectric layer. In some embodiments, a feature may have an aspect ratio of at least about 2:1, at least about 4:1, at least about 6:1, at least about 10:1, at least about 25:1, or higher. One example of a feature is a hole or via in a semiconductor substrate or a layer on the substrate.

FIG. 2A depicts a schematic example of a DRAM architecture including a metal buried wordline (bWL) 208 in a silicon substrate 202. The metal bWL is formed in a trench etched in the silicon substrate 202. Lining the trench is a conformal barrier layer 206 and an insulating layer 204 that is disposed between the conformal barrier layer 206 and the silicon substrate 202. In the example of FIG. 2A, the insulating layer 204 may be a gate oxide layer, formed from a high-k dielectric material such as a silicon oxide or silicon nitride material. In some embodiments disclosed herein the conformal barrier layer is TiN or tungsten-containing layer. In some embodiments, one or both of layers 204 and 206 is not present.

The bWL structure shown in FIG. 2A is one example of an architecture that includes a conductive metal fill layer. During fabrication of the bWL, a conductive metal film is deposited into a feature that may be defined by an etched recess in the silicon substrate 202 that is conformally lined with layers 206 and 204, if present.

FIGS. 2B-2H are additional schematic examples of various structures into which a metal fill layer may be deposited in accordance with disclosed embodiments. FIG. 2B shows an example of a cross-sectional depiction of a vertical feature 201 to be filled with metal. The feature can include a feature hole 205 in a substrate 202. The hole 205 or other feature may have a dimension near the opening, e.g., an opening diameter or line width of between about 10 nm to 500 nm, for example between about 25 nm and about 300 nm. The feature hole 205 can be referred to as an unfilled feature or simply a feature. The feature 201, and any feature, may be characterized in part by an axis 218 that extends through the length of the feature, with vertically-oriented features having vertical axes and horizontally-oriented features having horizontal axes.

In some embodiments, features are wordline features in a 3D NAND structure. For example, a substrate may include a wordline structure having an arbitrary number of wordlines (e.g., 50 to 150) with vertical channels at least 200 Å deep. Another example is a trench in a substrate or layer. Features may be of any depth. In various embodiments, the feature may have an under-layer, such as a barrier layer or adhesion layer. Non-limiting examples of under-layers include dielectric layers and conducting layers, e.g., silicon oxides, silicon nitrides, silicon carbides, metal oxides, metal nitrides, metal carbides, and metal layers.

FIG. 2C shows an example of a feature 201 that has a re-entrant profile. A re-entrant profile is a profile that narrows from a bottom, closed end, or interior of the feature to the feature opening. According to various implementations, the profile may narrow gradually and/or include an overhang at the feature opening. FIG. 2C shows an example of the latter, with an under-layer 213 lining the sidewall or interior surfaces of the feature hole 105. The under-layer 213 can be for example, a diffusion barrier layer, an adhesion layer, a nucleation layer, a combination of thereof, or any other applicable material. Non-limiting examples of under-layers can include dielectric layers and conducting layers, e.g., silicon oxides, silicon nitrides, silicon carbides, metal oxides, metal nitrides, metal carbides, and metal layers. In particular implementations an under-layer can be one or more of titanium, titanium nitride, tungsten nitride, titanium aluminide, tungsten, and molybdenum. In some embodiments, the under-layer is different from or does not contain the metal of the metal conductive layer. In some embodiments, the under-layer is tungsten-free. In some embodiments, the under-layer is molybdenum-free. The under-layer 213 forms an overhang 215 such that the under-layer 213 is thicker near the opening of the feature 201 than inside the feature 201.

In some implementations, features having one or more constrictions within the feature may be filled. FIG. 2D shows examples of views of various filled features having constrictions. Each of the examples (a), (b) and (c) in FIG. 2D includes a constriction 209 at a midpoint within the feature. The constriction 209 can be, for example, between about 15 nm-20 nm wide. Constrictions can cause pinch off during deposition of tungsten or molybdenum in the feature using conventional techniques, with deposited metal blocking further deposition past the constriction before that portion of the feature is filled, resulting in voids in the feature. Example (b) further includes a liner/barrier overhang 215 at the feature opening. Such an overhang could also be a potential pinch-off point. Example (c) includes a constriction 212 further away from the field region than the overhang 215 in example (b).

Horizontal features, such as in 3-D memory structures, can also be filled. FIG. 2E shows an example of a horizontal feature 250 that includes a constriction 251. For example, horizontal feature 250 may be a word line in a 3D NAND (also referred to as vertical NAND or VNAND) structure. In some implementations, the constrictions can be due to the presence of pillars in a 3D NAND or other structure. FIG. 2F presents a cross-sectional side-view of a 3-D NAND structure 210 (formed on a silicon substrate 202) having VNAND stacks (left 225 and right 226), central vertical structure 230, and a plurality of stacked horizontal features 220 with openings 222 on opposite sidewalls 240 of central vertical structure 230. Note that FIG. 2F displays two “stacks” of the exhibited 3-D NAND structure 210, which together form the “trench-like” central vertical structure 230, however, in certain embodiments, there may be more than two “stacks” arranged in sequence and running spatially parallel to one another, the gap between each adjacent pair of “stacks” forming a central vertical structure 230, like that explicitly illustrated in FIG. 2F. In this embodiment, the horizontal features 120 are 3-D memory wordline features that are fluidically accessible from the central vertical structure 230 through the openings 222. Although not explicitly indicated in the figure, the horizontal features 220 present in both the 3-D NAND stacks 225 and 226 shown in FIG. 2F (i.e., the left 3-D NAND stack 225 and the right 3-D NAND stack 226) are also accessible from the other sides of the stacks (far left and far right, respectively) through similar vertical structures formed by additional 3-D NAND stacks (to the far left and far right, but not shown). In other words, each 3-D NAND stack 225, 226 contains a stack of wordline features that are fluidically accessible from both sides of the 3-D NAND stack through a central vertical structure 1230. In the particular example schematically illustrated in FIG. 2F, each 3-D NAND stack contains 6 pairs of stacked wordlines, however, in other embodiments, a 3-D NAND memory layout may contain any number of vertically stacked pairs of wordlines.

The wordline features in a 3-D NAND stack are typically formed by depositing an alternating stack of silicon oxide and silicon nitride layers, and then selectively removing the nitride layers leaving a stack of oxides layers having gaps between them. These gaps are the wordline features. Any number of wordlines may be vertically stacked in such a 3-D NAND structure so long as there is a technique for forming them available, as well as a technique available to successfully accomplish (substantially) void-free fills of the vertical features. Thus, for example, a VNAND stack may include between 2 and 256 horizontal wordline features, or between 8 and 128 horizontal wordline features, or between 16 and 64 horizontal wordline features, and so forth (the listed ranges understood to include the recited end points).

FIG. 2G presents a cross-sectional top-down view of the same 3-D NAND structure 210 shown in side-view in FIG. 2F with the cross-section taken through the horizontal section 260 as indicated by the dashed horizontal line in FIG. 2F. The cross-section of FIG. 2G illustrates several rows of pillars 255, which are shown in Figure IF to run vertically from the base of semiconductor substrate 202 to the top of 3-D NAND stack 210. In some embodiments, these pillars 255 are formed from a polysilicon material and are structurally and functionally significant to the 3-D NAND structure 210. In some embodiments, such polysilicon pillars may serve as gate electrodes for stacked memory cells formed within the pillars. The top-view of FIG. 2G illustrates that the pillars 255 form constrictions in the openings 222 to wordline features 220—i.e. fluidic accessibility of wordline features 220 from the central vertical structure 230 via openings 222 (as indicated by the arrows in FIG. 2G) is inhibited by pillars 255. In some embodiments, the size of the horizontal gap between adjacent polysilicon pillars is between about 1 and 20 nm. This reduction in fluidic accessibility increases the difficulty of uniformly filling wordline features 120 with conductive metal film. The structure of wordline features 220 and the challenge of uniformly filling them with conductive metal material due to the presence of pillars 255 is further illustrated in FIGS. 2H, 2I, and 2J.

FIG. 2H exhibits a vertical cut through a 3-D NAND structure similar to that shown in FIG. 2F, but here focused on a single pair of wordline features 220 and additionally schematically illustrating a fill process which resulted in the formation of a void 275 in the filled wordline features 220. FIG. 2I also schematically illustrates void 175, but in this figure illustrated via a horizontal cut through pillars 155, like the horizontal cut exhibited in FIG. 2G. FIG. 2J illustrates the accumulation of metal (e.g., W or Mo) around the constriction-forming pillars 255, the accumulation resulting in the pinch-off of openings 222, so that no additional W, Mo, or other metal can be deposited in the region of voids 275. Apparent from FIGS. 2H and 2I is that void-free till relies on migration of sufficient quantities of deposition precursor down through vertical structure 230, through openings 222, past the constricting pillars 255, and into the furthest reaches of wordline features 220, prior to the accumulated deposition of metal around pillars 255 causing a pinch-off of the openings 222 and preventing further precursor migration into wordline features 220. Similarly, FIG. 2J exhibits a single wordline feature 220 viewed cross-sectionally from above and illustrates how a generally conformal deposition of metal begins to pinch-off the interior of wordline feature 220 due to the fact that the significant width of pillars 255 acts to partially block, and/or narrow, and/or constrict what would otherwise be an open path through wordline feature 220. (It should be noted that the example in FIG. 2J can be understood as a 2-D rendering of the 3-D features of the structure of the pillar constrictions shown in FIG. 21, thus illustrating constrictions that would be seen in a plan view rather than in a cross-sectional view.)

Three-dimensional structures may need longer and/or more concentrated exposure to precursors to allow the innermost and bottommost areas to be filled. Three-dimensional structures can be particularly challenging when employing molybdenum halide and/or molybdenum oxyhalide precursors because of their proclivity to etch, with longer and more concentrated exposure allowing for more etch as parts of the structure.

In some embodiments, the methods involve deposition of a first metal layer in a feature. The first metal layer may be a nucleation layer, a bulk layer, or a bulk layer deposited on a nucleation layer. It may be deposited by an ALD process to conformity line the feature. The first metal layer may be exposed to an inhibition treatment. In some embodiments, the inhibition treatment is preferentially applied near the top of the feature, such that subsequent deposition in the bottom of the feature is not inhibited or inhibited to a lesser extent than near the top. This results in bottom-up fill.

The methods may also be used to fill multiple adjacent features, such as DRAM bWL trenches. Fill processes for DRAM bWL trenches can distort the trenches such that the final trench width and resistance Rs are significantly non-uniform. This phenomenon is referred to as line bending. FIG. 2K shows an unfilled (231) and filled (235) narrow asymmetric trench structure DRAM bWL that exhibit line bending after fill. As shown, multiple features are depicted on a substrate. These features are spaced apart, and in some embodiments, adjacent features have a pitch between about 20 nm and about 60 nm or between about 20 nm and 40 nm. The pitch is defined as the distance between the middle axis of one feature to the middle axis of an adjacent feature. The unfilled features may be generally V-shaped as shown in feature 203, having sloped sidewalls where the width of the feature narrows from the top of the feature to the bottom of the feature. The features widen from the feature bottom to the feature top. Sequences of depositions that use inhibition may be used to mitigate line bending. These include inhibiting the full depth of the features.

Examples of feature fill for horizontally-oriented and vertically-oriented features are described below. It should be noted that in at least most cases, the examples are applicable to both horizontally-oriented or vertically-oriented features. Moreover, it should also be noted that in the description below, the term “lateral” may be used to refer to a direction generally orthogonal to the feature axis and the term “vertical” to refer to a direction generally along the feature axis.

Embodiments of the methods described herein employ plasmas including oxygen species to modulate or remove a nucleation inhibition effect. In some embodiments, they may be implemented as part of a deposition-inhibition-deposition (DID) sequence for feature fill.

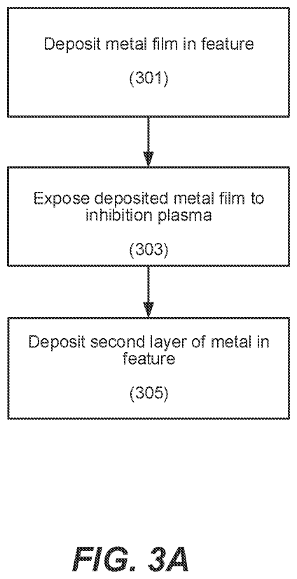

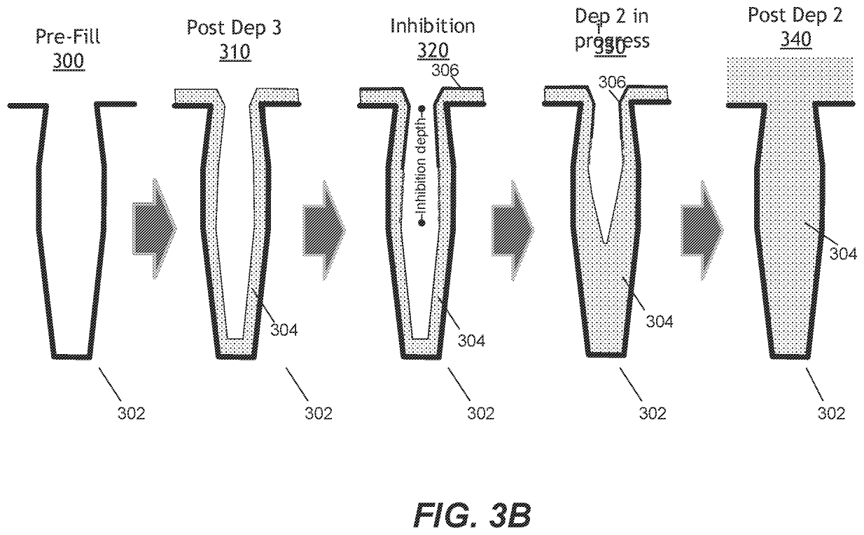

FIG. 3A is a process flow diagram illustrating operations in filling a structure with a metal according to various embodiments and FIG. 3B shows a schematic of a cross-section of feature at various stages in according to an embodiment of the process in FIG. 3A.

In FIG. 3B, at 300, an unfilled feature 302 is shown at a pre-fill stage. The feature 302 may be formed in one or more layers on a semiconductor substrate and may optionally have one or more layers that line the sidewalls and/or bottom of the feature. Turning to FIG. 3A, a metal film is deposited in the feature in an operation 301. This operation may be referred to as Dep1. In many embodiments, operation 301 is a generally conformal deposition that lines the exposed surfaces of the structures. For example, in a 3D NAND structure such as that shown in FIG. 2F, the metal film lines the wordline features 220. According to various embodiments, the metal film is deposited using an atomic layer deposition (ALD) process to achieve good conformality. Chemical vapor deposition (CVD) processes may be used in alternate embodiments. Still further, the process may also be carried out with any appropriate metal deposition including physical vapor deposition (PVD) or plating processes. In some embodiments, after operation 301, the features are not closed off, but sufficiently open to allow further reactant gases to enter the features in a subsequent deposition.

In an ALD process, the feature is exposed to alternating pulses of reactant gases. In the example of tungsten deposition, a tungsten-containing precursor such as tungsten hexafluoride (WF₆), tungsten hexachloride (WCl₆), tungsten pentachloride (WCl₅), tungsten hexacarbonyl (W(CO)₆), or a tungsten-containing organometallic compound may be used. In some embodiments, pulses of the tungsten-containing precursor are pulsed with a reducing agent such as hydrogen (H₂), diborane (B₂H₆), silane (SiH₄), or germane (GeH₄). In a CVD method, the wafer is exposed to the reactant gases simultaneously. Deposition chemistries for other films are provided below. In FIG. 3B, at 310, the feature 302 is shown after Dep1 to form a layer of the material 304 to be filled in the feature 302.

Next, in an operation 303 in FIG. 3A, the deposited metal film is exposed to an inhibition plasma. This may be a conformal or non-conformal treatment. A non-conformal treatment in this context refers to the treatment being preferentially applied at and near the opening or openings of the feature than in the feature interior. For 3D NAND structures, the treatment may be conformal in the vertical direction such that the bottom wordline feature is treated to approximately the same extent as the top wordline feature, while non-conformal in that the interior of the wordline features are not exposed to the treatment or to a significantly lesser extent than the feature openings. A conformal treatment refers to the entire feature being treated to roughly the same extent. Such a treatment may be performed to mitigate line bending, for example, of the features in FIG. 2K.

The inhibition plasma treats the feature surface to inhibit subsequent metal nucleation at the treated surfaces. It can involve one or more of: deposition of an inhibition film, reaction of plasma species with the Dep1 film to form a compound film (e.g., WN or Mo₂N), and adsorption of inhibition species. During the subsequent deposition operation, there is a nucleation delay on the inhibited portions of the underlying film relative to the non- or lesser-inhibited portions (if any). In some embodiments, a non-plasma operation may be used instead of a plasma operation. If a non-plasma operation, it may be purely thermal or activated by some other energy such as UV. In some embodiments, the inhibition operation includes exposure to a metal precursor, which can be co-flowed with the inhibition gas or delivered in alternating pulses with it.

The plasma may be a remote or in-situ plasma. In some embodiments, it is generated from nitrogen (N₂) gas, though other nitrogen-containing gases may be used. In some embodiments, the plasma is a radical-based plasma, with no appreciable number of ions. Such plasmas are typically remotely generated. Nitrogen radicals may react with an underlying film to form a metal nitride in some embodiments. For thermal inhibition treatments, a nitrogen- and hydrogen-containing compound such as ammonia (NH₃) may be used.

In FIG. 3B, at 320 the feature 302 is shown after an inhibition treatment. The inhibition treatment is a treatment that has the effect of inhibiting subsequent deposition on the treated surfaces 306. The inhibition may be characterized by an inhibition depth and an inhibition gradient. For non-conformal inhibitions, the inhibition varies with feature depth, e.g., such that the inhibition is greater at the feature opening than at the bottom of the feature, and may extend only partway into the feature. In the depicted example of FIG. 3B, the inhibition depth is about half of the full feature depth. In addition, the inhibition treatment is stronger at the top of the feature, as graphically shown by the dotted line deeper within the feature. As indicated above, in other embodiments, the inhibition may be uniform throughout the feature.

Returning to FIG. 3A, after operation 303, a second layer of metal is deposited in the feature in an operation 304. The second deposition may be referred to as Dep2 and may be performed by an ALD or CVD process. For deposition into 3D NAND structures, an ALD process may be used to allow for good step coverage throughout the structure. The Dep2 operation is influenced by the preceding inhibition operation. For example, if the feature openings are preferentially inhibited over the feature interior, deposition will preferentially occur in the feature interior. In another example, nitrogen on the surface of the deposited metal along the sidewalls of the feature may prevent metal-metal (e.g., tungsten-tungsten bonding) thereby reducing line bending.

In the example of FIG. 3B, because deposition is inhibited near the feature opening, during the Dep2 stage shown at 330, the material preferentially deposits at the feature bottom while not depositing or depositing to a less extent at the feature opening. This can prevent the formation of voids and seams within the filled feature. As such, during Dep2, the material 304 may be filled in a manner characterized as bottom-up fill rather than the conformal Dep1 fill. As the deposition continues, the inhibition effect may be removed, such that deposition on the lightly treated surfaces may no longer be inhibited. This is illustrated at 330, with the treated surfaces 306 being less extensive than prior to the Dep2 stage. In the example of FIG. 3B, as the Dep2 proceeds, the inhibition is eventually overcome on all surfaces and the feature is completely filled with the material 304 as shown at 340. While the DID process in FIG. 3B shows the feature preferentially inhibited at the top of the feature, in some embodiments, the entire feature may be inhibited. Such a process can be useful for preventing line bending, for example.

Embodiments of the methods described herein employ plasmas including oxygen species to modulate the inhibition effect and may be implemented as part of a DID sequence in some embodiments. In other embodiments, they may be part of any process sequence that includes an inhibition operation, including inhibition-deposition, inhibition-deinhibition, etc. In some embodiments, the oxygen species are oxygen radicals generated in a remote plasma generator.

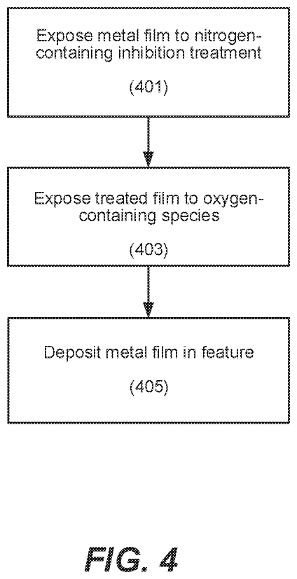

In some embodiments, oxygen is used to increase a nucleation delay (i.e., increase the inhibition effect.) FIG. 4 shows an example of a process flow diagram illustrating operations in a method of increasing a nucleation delay.

In the example of FIG. 4, a metal film (e.g., W) is exposed to a nitrogen-containing inhibition treatment to form a treated film in an operation 401. In some embodiments, the treatment forms a metal nitride (e.g., WN). Nitrogen species may instead or also be adsorbed onto the metal surface. Operation 401 may be performed as part of operation 303 in FIG. 3A for example, or as part of any inhibition treatment. In many embodiments, operation 401 involves exposing a metal film to nitrogen radicals. The nitrogen radicals may be generated using a remote plasma generator from nitrogen (N₂) gas in some embodiments. In alternate embodiments, operation 401 can involve a thermal process, e.g., exposing the metal film to an ammonia gas. The treatment in operation 401 is typically only a surface treatment such that most to the film thickness remains metal, with a metal nitride and/or adsorbed nitrogen atoms at the surface. The treatment in operation 401 inhibits nucleation, leading to a nucleation delay.

Next in an operation 403, the treated film is exposed to oxygen-containing species. These may be oxygen radicals, which can be generated, e.g., in a remote plasma generator from oxygen (O₂) gas. Notably, the substrate is not exposed to nitrogen during this operation. Operation 403 increases the inhibition and the nucleation delay. In one example, nucleation delay tripled from 20 s after a N₂ remote plasma to 60 s after an N₂ plasma followed by a O₂ remote plasma. In some embodiments, exposure to oxygen results in metal oxynitride (e.g., WNOₓ) formation, which increases nucleation delay.

In alternate embodiments, oxygen species may be used to inhibit metal nucleation on any metal nitride surface.

Operation 403 is often a plasma treatment, using oxygen radicals generated in a remote plasma generator. In some embodiments, operation 404 is a non-plasma process. Molecular oxygen (O₂) may be activated with UV light for example. In some embodiments, an ozone source may be used to provide activated oxygen species. The oxygen species may be generated in a plasma source using any appropriate oxygen-containing gas. As noted above, nitrogen is generally not present. Further, in some embodiments, hydrogen or other reductant may be avoided.

Operation 403 may be used to increase inhibition and nucleation delay without performing other techniques that can increase inhibition such as raising RF power. In some embodiments, RF power of less than 1000 W (per 300 mm wafer or 3.33 W/mm) can be used to provide a very long nucleation delay when using nitrogen and oxygen in sequence. Notably, when a tungsten film is exposed to oxygen alone, it does not inhibit at all.

Operation 403 may be performed as part of operation 303 in FIG. 3A for example, or as part of any inhibition treatment. In some embodiments, one or more further treatment operations is performed after operation 403 and prior to deposition of metal. Such a treatment can include further inhibition (e.g., exposure to N radicals) or de-inhibition treatments (e.g., exposure to N₂/O₂ co-flow as described below). In other embodiments, the no intervening treatments are performed before subsequent metal deposition. A metal film is deposited in the feature in operation 405. This operation may be performed as described above with respect to operation 305 in FIG. 3A.

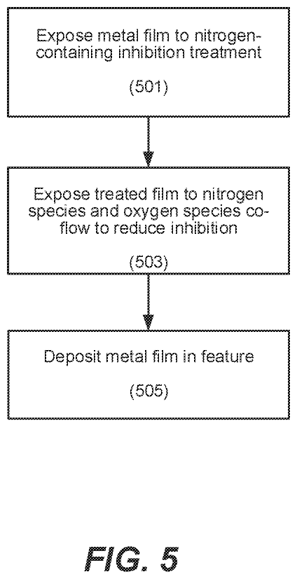

In the above description that references FIG. 4, exposure to oxygen is used to increase nucleation delay after a nitrogen inhibition treatment. In some embodiments, a nitrogen/oxygen co-flow may be used to decrease or eliminate nucleation delay. FIG. 5 shows an example of a process that may be used for feature fill. First, in an operation 501, a metal film is exposed to nitrogen-containing inhibition treatment. Operation 501 may be performed as described above with reference to operation 401 of FIG. 4. Then, in an operation 503, the substrate may be exposed to a co-flow of nitrogen and oxygen species, e.g., nitrogen radicals and oxygen radicals. This has the effect of reducing the inhibition. Operation 503 may be performed to modulate the inhibition (e.g., reduce nucleation delay on treated surfaces from 20 s to 10 s) or to remove the inhibition entirely. As described further below, the latter implementation may be useful to “reset” the substrate surface, for example, after an unforeseen production delay. A 50:50 (atomic) O:N ratio may be used with other ratios such as 10:90-90:10 or 25:75-75:25 also possible. The ratio may be tuned to vary the extent of the reset.

In some embodiments, operation 503 may be performed without first performing operation 501. That is, a metal surface may be exposed to the oxygen and nitrogen species co-flow with previously exposing the surface to a nitrogen treatment without oxygen. The amount of oxygen may be used to tune the inhibition. In some such embodiments, the flow may be mostly nitrogen radicals such that the O:N ratio is less 1:2, or less than 1:3, or less than 1:4.

Methods of resetting an inhibited surface are also provided. Once nucleation is inhibited, one method of removing the inhibition is to expose it to a metal precursor and reducing agent (e.g., WF₆ and H₂). However, this method of removing inhibition leads to metal growing on the surface. There are various scenarios in a fabrication facility in which de-inhibition capability without the possibility of metal deposition is useful.

In some embodiments, for example, a de-inhibition treatment may be performed if an unforeseen lag occurs between inhibition and deposition. Such a lag can by itself reduce the inhibition effect and the nucleation delay and result in non-uniform wafer-to-wafer processing. The wafer can be reset and then re-inhibited to achieve the same nucleation delay as if there were never a lag.

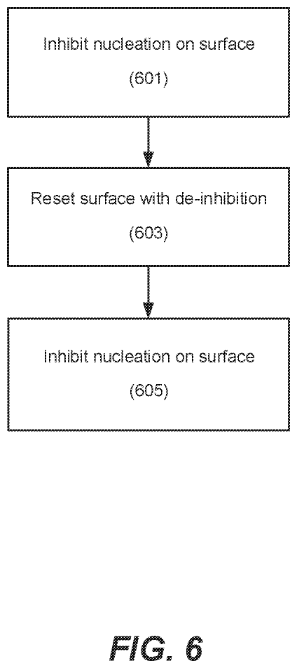

FIG. 6 shows a process flow diagram illustrating certain operations in a method of inhibiting a surface with a reset. In FIG. 6, nucleation is inhibited on a surface (601). This operation may be performed as described with reference to operation 303 of FIG. 3A, with reference to operations 401 and 403 of FIG. 4, or operations 501 and/or 503 in FIG. 5, for example. Then, in an operation 603, the surface is reset with a de-inhibition treatment. Exposing an inhibited surface to a 50:50 oxygen radical:nitrogen radical co-flow for a sufficient time, for example, can eliminate the inhibition. Operation 603 may be performed for example, if a deposition module or other module in the wafer path has unscheduled downtime. Once the process is ready to be restarted, nucleation is inhibited on the surface in an operation 605 as described above. In some embodiments, the method in FIG. 6 is performed after receiving an indication of a delay such as unscheduled downtime.

A tungsten film was exposed to the various treatments with nucleation delay measured after each treatment.

| Treatment | Nucleation delay | |
|---|---|---|
| 1 - N₂ remote plasma (1 sec) | 20 | sec |
| 2 - N₂ remote plasma (1 sec) + | 64 | sec |
| O₂ remote plasma (1 sec) | | |
| 3 - N₂ remote plasma (5 sec) | 101 | sec |
| 4 - N₂ remote plasma (5 sec) + | 2 | sec |
| 50:50 O₂:N₂ remote plasma (1 sec) | | |
| 5- O₂ remote plasma (1 sec) | 2 | sec |

The above results show several effects of oxygen plasma treatment. First, comparing treatment (1) to treatment (2), it can be seen using O₂ after N₂ can increase the nucleation delay significantly. Treatment (4) shows that even after a significant inhibition (100 secs delay), a N₂/O₂ co-flow plasma can completely de-inhibit or reset the surface. Finally, treatment (5) shows that O₂ by itself does not inhibit tungsten growth. Longer N₂ treatment (3) increases nucleation delay but prolongs the process, reducing throughput and increasing plasma exposure. The latter can cause front end transistor damage or back end low-k damage.

Nucleation delay was measured directly after inhibition and compared to nucleation delay with a 30 min lag between inhibition and deposition. Nucleation delay decreased from 20 seconds less than 10 seconds. This shows that resetting the surface as described above can be advantageous in situations in which deposition is unexpectedly delayed.

As indicated above, in many embodiments the nitrogen and/or oxygen inhibition species are primarily or essentially all radical species. Other types of species (molecular and/or ionic) may be used in some embodiments.

Also as indicated above, the plasma generator may be remote to the processing chamber with radical species inlet via a showerhead or other inlet. In situ plasma generators may be used in alternate embodiments.

In addition to plasma-based nitridation and oxidation, the nitridation and/or oxidation described above may be achieved with other types of activation (e.g., UV or thermal) and/or other nitrogen-containing or oxygen-containing chemistries. In some embodiments, for example, a nitrogen- and oxygen-containing compound such NO₂ or N₂O may be used in some embodiments for de-inhibition. It should be noted that while exposure to air can decrease the inhibition effect somewhat, completely de-inhibiting the surface as described above may be implemented with a plasma co-flow as described above.

### Metal-Containing Precursors

While WF₆ is used as an example of a tungsten-containing precursor in the above description, it should be understood that other tungsten-containing precursors may be suitable for performing disclosed embodiments. For example, a metal-organic tungsten-containing precursor may be used. Organo-metallic precursors and precursors that are free of fluorine, such as MDNOW (methylcyclopentadienyl-dicarbonylnitrosyl-tungsten) and EDNOW (ethylcyclopentadienyl-dicarbonylnitrosyl-tungsten) may also be used. Chlorine-containing tungsten precursors (WClₓ) such as tungsten pentachloride (WCl₅) and tungsten hexachloride (WCl₆) may be used.

To deposit molybdenum (Mo), Mo-containing precursors including molybdenum hexafluoride (MoF₆), molybdenum pentachloride (MoCl₅), molybdenum dichloride dioxide (MoO₂Cl₂), molybdenum tetrachloride oxide (MoOCl₄), and molybdenum hexacarbonyl (Mo(CO)₆) may be used.

To deposit ruthenium (Ru), Ru-precursors may be used. Examples of ruthenium precursors that may be used for oxidative reactions include (ethylbenzyl)(1-ethyl-1,4-cyclohexadienyl)Ru(0), (1-isopropyl-4-methylbenzyl)(1,3-cyclohexadienyl)Ru(0), 2,3-dimethyl-1,3-butadienyl)Ru(0)tricarbonyl, (1,3-cyclohexadienyl)Ru(0)tricarbonyl, and (cyclopentadienyl)(ethyl)Ru(II)dicarbonyl. Examples of ruthenium precursors that react with non-oxidizing reactants are bis(5-methyl-2,4-hexanediketonato)Ru(II)dicarbonyl and bis(ethylcyclopentadienyl)Ru(II).

To deposit cobalt (Co), cobalt-containing precursors including dicarbonyl cyclopentadienyl cobalt (I), cobalt carbonyl, various cobalt amidinate precursors, cobalt diazadienyl complexes, cobalt amidinate/guanidinate precursors, and combinations thereof may be used.

The metal-containing precursor may be reacted with a reducing agent as described above. In some embodiments, H₂ is used as a reducing agent for bulk layer deposition to deposit high purity films.

### Nucleation Layer Deposition

In some implementations, the methods described herein involve deposition of a nucleation layer prior to deposition of a bulk layer. A nucleation layer is typically a thin conformal layer that facilitates subsequent deposition of bulk material thereon. For example, a nucleation layer may be deposited prior to any fill of the feature and/or at subsequent points during fill of the feature (e.g., via interconnect) on a water surface. For example, in some implementations, a nucleation layer may be deposited following etch of tungsten in a feature, as well as prior to initial tungsten deposition.

In certain implementations, the nucleation layer is deposited using a pulsed nucleation layer (PNL) technique. In a PNL technique to deposit a tungsten nucleation layer, pulses of a reducing agent, optional purge gases, and tungsten-containing precursor are sequentially injected into and purged from the reaction chamber. The process is repeated in a cyclical fashion until the desired thickness is achieved. PNL broadly embodies any cyclical process of sequentially adding reactants for reaction on a semiconductor substrate, including atomic layer deposition (ALD) techniques. Nucleation layer thickness can depend on the nucleation layer deposition method as well as the desired quality of bulk deposition. In general, nucleation layer thickness is sufficient to support high quality, uniform bulk deposition. Examples may range from 10 Å-100 Å.

The methods described herein are not limited to a particular method of nucleation layer deposition but include deposition of bulk film on nucleation layers formed by any method including PNL, ALD, CVD, and physical vapor deposition (PVD). Moreover, in certain implementations, bulk tungsten may be deposited directly in a feature without use of a nucleation layer. For example, in some implementations, the feature surface and/or an already-deposited under-layer supports bulk deposition. In some implementations, a bulk deposition process that does not use a nucleation layer may be performed.

In various implementations, nucleation layer deposition can involve exposure to a metal precursor as described above and a reducing agent. Examples of reducing agents can include boron-containing reducing agents including diborane (B₂H₆) and other boranes, silicon-containing reducing agents including silane (SiH₄) and other silanes, hydrazines, and germanes. In some implementations, pulses of metal-containing can be alternated with pulses of one or more reducing agents, e.g., S/W/S/W/B/W, etc., W representing a tungsten-containing precursor, S represents a silicon-containing precursor, and B represents a boron-containing precursor. In some implementations, a separate reducing agent may not be used, e.g., a tungsten-containing precursor may undergo thermal or plasma-assisted decomposition.

### Bulk Deposition

As described above, bulk deposition may be performed across a wafer. In some implementations, bulk deposition can occur by a CVD process in which a reducing agent and a metal-containing precursor are flowed into a deposition chamber to deposit a bulk fill layer in the feature. An inert carrier gas may be used to deliver one or more of the reactant streams, which may or may not be pre-mixed. Unlike PNL or ALD processes, this operation generally involves flowing the reactants continuously until the desired amount is deposited. In certain implementations, the CVD operation may take place in multiple stages, with multiple periods of continuous and simultaneous flow of reactants separated by periods of one or more reactant flows diverted. Bulk deposition may also be performed using ALD processes in which a metal-containing precursor is alternated with a reducing agent such as H₂.

It should be understood that the metal films described herein may include some amount of other compounds, dopants and/or impurities such as nitrogen, carbon, oxygen, boron, phosphorous, sulfur, silicon, germanium and the like, depending on the particular precursors and processes used. The metal content in the film may range from 20% to 100% (atomic) metal. In many implementations, the films are metal-rich, having at least 50% (atomic) metal, or even at least about 60%, 75%, 90%, or 99% (atomic) metal. In some implementations, the films may be a mixture of metallic or elemental metal (e.g., W, Mo, Co, or Ru) and other metal-containing compounds such as tungsten carbide (WC), tungsten nitride (WN), molybdenum nitride (MoN) etc. CVD and ALD deposition of these materials can include using any appropriate precursors as described above.

### Inhibition of Metal Nucleation

Plasma inhibition processes involve exposure to a plasma generated from a nitrogen containing compound, such as N₂. Plasma power, chamber pressure, and/or process gases may be pulsed in some embodiments.

Thermal inhibition processes generally involve exposing the feature to a nitrogen-containing compound such as ammonia (NH₃) or hydrazine (N₂H₄) to non-conformally inhibit the feature near the feature opening. In some embodiments, the thermal inhibition processes are performed at temperatures ranging from 250° C. to 450° C. At these temperatures, exposure of a previously formed tungsten or other layer to NH₃ results in an inhibition effect. Other potentially inhibiting chemistries such as nitrogen (N₂) or hydrogen (H₂) may be used for thermal inhibition at higher temperatures (e.g., 900° C.). For many applications, however, these high temperatures exceed the thermal budget. In addition to ammonia, other hydrogen-containing nitriding agents such as hydrazine may be used at lower temperatures appropriate for back end of line (BEOL) applications. During thermal inhibition, a metal precursor may be flowed with the inhibition gas or in alternating pulses with the gas.

Nitridation of a surface can passivate it. Subsequent deposition of tungsten or other metal such as molybdenum or cobalt on a nitrided surface is significantly delayed, compared to on a regular bulk tungsten film. In addition to NF₃, fluorocarbons such as CF₄ or C₂F₈ may be used. However, in certain implementations, the inhibition species are fluorine-free to prevent etching during inhibition.

In addition to the surfaces described above, nucleation may be inhibited on liner/barrier layers surfaces such as TiN and/or WN surfaces. Any chemistry that passivates these surfaces may be used. Inhibition chemistry can also be used to tune an inhibition profile, with different ratios of active inhibiting species used. For example, for inhibition of W surfaces, nitrogen may have a stronger inhibiting effect than hydrogen; adjusting the ratio of N₂ and H₂ gas in a forming gas can be used to tune a profile.

In certain implementations, the substrate can be heated up or cooled down before inhibition. A predetermined temperature for the substrate can be selected to induce a chemical reaction between the feature surface and inhibition species and/or promote adsorption of the inhibition species, as well as to control the rate of the reaction or adsorption. For example, a temperature may be selected to have high reaction rate such that more inhibition occurs near the gas source.

After inhibition, the inhibition effect may be modulated as described above. In the same or other embodiments, it may also be modulated by soaking it in a reducing agent or metal precursor, exposing it to a hydrogen-(H-)containing plasma, performing a thermal anneal, exposing it an air, which can reduce the inhibition effect.

One or more treatments to modulate the inhibition effect may also be performed before the inhibition treatment. For example, a reducing agent soak may be used to increase the inhibition effect.

### Apparatus

Any suitable chamber may be used to implement the disclosed embodiments. Example deposition apparatuses include various systems, e.g., ALTUS® and ALTUS® Max, available from Lam Research Corp., of Fremont, Calif., or any of a variety of other commercially available processing systems.

In some embodiments, a first deposition may be performed at a first station that is one of two, five, or even more deposition stations positioned within a single deposition chamber. Thus, for example, hydrogen (H₂) and tungsten hexachloride (WF₆) may be introduced in alternating pulses to the surface of the semiconductor substrate, at the first station, using an individual gas supply system that creates a localized atmosphere at the substrate surface. Another station may be used for inhibition treatment, and a third and/or fourth for subsequent ALD bulk fill. In some embodiments, the inhibition may be performed in a separate module.

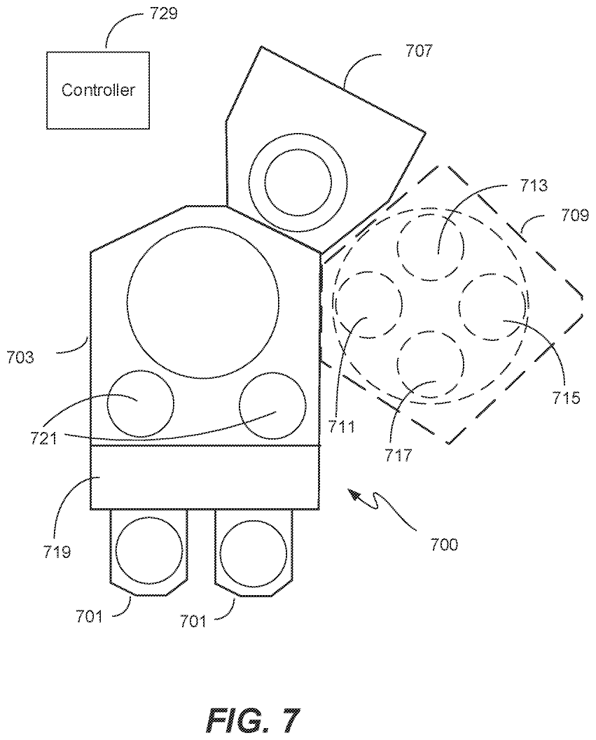

FIG. 7 is a schematic of a process system suitable for conducting deposition processes in accordance with embodiments. The system 700 includes a transfer module 703. The transfer module 703 provides a clean, pressurized environment to minimize risk of contamination of substrates being processed as they are moved between various reactor modules. Mounted on the transfer module 703 is a multi-station reactor 709 capable of performing ALD, CVD, and treatments such as inhibition treatment and de-inhibition treatment according to various embodiments. Multi-station reactor 709 may include multiple stations 711, 713, 715, and 717 that may sequentially perform operations in accordance with disclosed embodiments. For example, multi-station reactor 709 may be configured such that station 711 performs a W, Mo, Co, or Ru nucleation layer deposition using a metal precursor and a boron- or silicon-containing reducing agent, station 713 performs an ALD W, Mo, Co, or Ru bulk deposition of a conformal layer using as reducing agent, station 715 performs an inhibition treatment operation, and station 717 may perform another ALD bulk deposition to fill the feature. Stations may include a heated pedestal or substrate support, one or more gas inlets or showerhead or dispersion plate.

In some embodiments, the multi-station module may be used for deposition (and other processes such as etch) with inhibition performed in a separate module such as module 707.

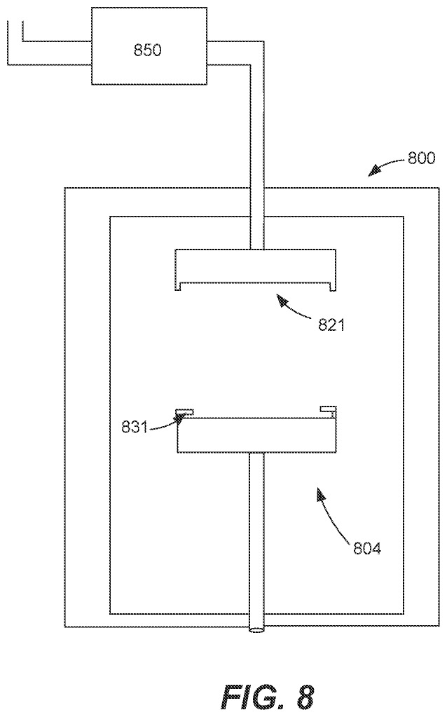

One example of a station is depicted in FIG. 8, which shows a station configured for semiconductor processing. The station is connected to a remote plasma generator 850 and has a showerhead 821 and substrate support 804. On top of the substrate support is a carrier ring 831.

Returning to FIG. 7, also mounted on the transfer module 703 may be one or more single or multi-station modules 707 capable of performing plasma or chemical (non-plasma) pre-cleans, plasma or non-plasma inhibition operations, other deposition operations, or etch operations. The module may also be used for various treatments to, for example, prepare a substrate for a deposition process. The system 700 also includes one or more wafer source modules 701, where wafers are stored before and after processing. An atmospheric robot (not shown) in the atmospheric transfer chamber 719 may first remove wafers from the source modules 701 to loadlocks 721. A wafer transfer device (generally a robot arm unit) in the transfer module 703 moves the wafers from loadlocks 721 to and among the modules mounted on the transfer module 703.

In various embodiments, a system controller 729 is employed to control process conditions during deposition. The controller 729 will typically include one or more memory devices and one or more processors. A processor may include a CPU or computer, analog and/or digital input/output connections, stepper motor controller boards, etc.

The controller 729 may control all the activities of the deposition apparatus. The system controller 729 executes system control software, including sets of instructions for controlling the timing, mixture of gases, chamber pressure, chamber temperature, wafer temperature, radio frequency (RF) power levels, wafer chuck or pedestal position, and other parameters of a particular process. Other computer programs stored on memory devices associated with the controller 729 may be employed in some embodiments.

Typically, there will be a user interface associated with the controller 729. The user interface may include a display screen, graphical software displays of the apparatus and/or process conditions, and user input devices such as pointing devices, keyboards, touch screens, microphones, etc.

System control logic may be configured in any suitable way. In general, the logic can be designed or configured in hardware and/or software. The instructions for controlling the drive circuitry may be hard coded or provided as software. The instructions may be provided by “programming.” Such programming is understood to include logic of any form, including hard coded logic in digital signal processors, application-specific integrated circuits, and other devices which have specific algorithms implemented as hardware. Programming is also understood to include software or firmware instructions that may be executed on a general purpose processor. System control software may be coded in any suitable computer readable programming language.

The computer program code for controlling the germanium-containing reducing agent pulses, hydrogen flow, and tungsten-containing precursor pulses, and other processes in a process sequence can be written in any conventional computer readable programming language: for example, assembly language, C, C++, Pascal, Fortran, or others. Compiled object code or script is executed by the processor to perform the tasks identified in the program. Also as indicated, the program code may be hard coded.

The controller parameters relate to process conditions, such as, for example, process gas composition and flow rates, temperature, pressure, cooling gas pressure, substrate temperature, and chamber wall temperature. These parameters are provided to the user in the form of a recipe and may be entered utilizing the user interface.

Signals for monitoring the process may be provided by analog and/or digital input connections of the system controller 729. The signals for controlling the process are output on the analog and digital output connections of the deposition apparatus 700.

The system software may be designed or configured in many ways. For example, various chamber component subroutines or control objects may be written to control operation of the chamber components necessary to carry out the deposition processes in accordance with the disclosed embodiments. Examples of programs or sections of programs for this purpose include substrate positioning code, process gas control code, pressure control code, and heater control code.

In some implementations, a controller 729 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller 729, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings in some systems, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller 729, in some implementations, may be a part of or coupled to a computer that is integrated with, coupled to the system, otherwise networked to the system, or a combination thereof. For example, the controller 729 may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus, as described above, the controller may be distributed, such as by including one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a CVD chamber or module, an ALD chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

The controller 629 may include various programs. A substrate positioning program may include program code for controlling chamber components that are used to load the substrate onto a pedestal or chuck and to control the spacing between the substrate and other parts of the chamber such as a gas inlet and/or target. A process gas control program may include code for controlling gas composition, flow rates, pulse times, and optionally for flowing gas into the chamber prior to deposition in order to stabilize the pressure in the chamber. A pressure control program may include code for controlling the pressure in the chamber by regulating, e.g., a throttle valve in the exhaust system of the chamber. A heater control program may include code for controlling the current to a heating unit that is used to heat the substrate. Alternatively, the heater control program may control delivery of a heat transfer gas such as helium to the wafer chuck.

Examples of chamber sensors that may be monitored during deposition include mass flow controllers, pressure sensors such as manometers, and thermocouples located in the pedestal or chuck. Appropriately programmed feedback and control algorithms may be used with data from these sensors to maintain desired process conditions.

The foregoing describes implementation of disclosed embodiments in a single or multi-chamber semiconductor processing tool. The apparatus and process described herein may be used in conjunction with lithographic patterning tools or processes, for example, for the fabrication or manufacture of semiconductor devices, displays, LEDs, photovoltaic panels, and the like. Typically, though not necessarily, such tools/processes will be used or conducted together in a common fabrication facility. Lithographic patterning of a film typically includes some or all of the following steps, each step provided with a number of possible tools: (1) application of photoresist on a workpiece, i.e., substrate, using a spin-on or spray-on tool; (2) curing of photoresist using a hot plate or furnace or UV curing tool; (3) exposing the photoresist to visible or UV or x-ray light with a tool such as a wafer stepper; (4) developing the resist so as to selectively remove resist and thereby pattern it using a tool such as a wet bench; (5) transferring the resist pattern into an underlying film or workpiece by using a dry or plasma-assisted etching tool; and (6) removing the resist using a tool such as an RF or microwave plasma resist stripper.

Unless otherwise stated, ranges in this disclosure are inclusive of the endpoints. For example, between 25:75-75:25 includes 25:75 and 75:25.

### CONCLUSION

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatus of the present embodiments. Accordingly, the present embodiments are to be considered as illustrative and not restrictive, and the embodiments are not to be limited to the details given herein.

1. A method comprising:
exposing a metal surface in a feature to a plasma comprising nitrogen species to inhibit metal nucleation on the metal surface; and
after exposing the metal surface to the plasma comprising nitrogen species, exposing the feature to a plasma comprising oxygen species and no nitrogen species to further inhibit metal nucleation on the metal surface.

2. The method of claim 1, further comprising, after exposing the metal surface to the plasma comprising oxygen species, depositing metal in the feature.

3. The method of claim 1, wherein the metal surface is one of a tungsten (W), molybdenum (Mo), ruthenium (Ru), or cobalt (Co) surface.

4. The method of claim 1, wherein the nitrogen species are nitrogen radicals.

5. The method of claim 1, wherein the oxygen species are oxygen radicals.

6. The method of claim 1, wherein the exposing the metal surface to the plasma comprising nitrogen species forms a metal nitride.

7. The method of claim 1, wherein exposing the feature to the plasma comprising oxygen forms a metal oxynitride.

8. The method of claim 1, wherein the plasma is remotely generated.

9. The method of claim 1, wherein plasma is a radical-based plasma with no ions.

10. The method of claim 1, wherein the metal surface is in a recessed feature to be filled with metal.

11. A method comprising:
after a treatment process that inhibits metal nucleation on a surface, exposing the treated surface to a plasma comprising oxygen species and nitrogen species to de-inhibit metal nucleation on the surface.

12. The method of claim 11, further comprising, prior to deposition on the surface and after de-inhibiting the surface, exposing the surface to nitrogen species to inhibit metal nucleation on the surface.

13. The method of claim 11, wherein the exposing the treated surface is performed in response to a delay.

14. The method of claim 13, further comprising receiving an indication of a delay.

15. The method of claim 11, further comprising, after de-inhibiting metal nucleation on the surface, exposing the surface to a treatment process that inhibits metal nucleation on the surface.

16. The method of claim 15, further comprising, after exposing the surface to the treatment process, depositing metal in the feature.

17. The method of claim 16, wherein the metal is one of tungsten (W), molybdenum (Mo), ruthenium (Ru), and cobalt (Co).

18. The method of claim 11, wherein the nitrogen species are nitrogen radicals.

19. The method of claim 11, wherein the oxygen species are oxygen radicals.

20. The method of claim 11, wherein the O:N ratio is between 10:90-90:10 (atomic).
